(19) United States
(12) Patent Application Publication
(10) Pub. No.: US 2025/0334625 A1
(43) Pub. Date: Oct. 30, 2025

(54) METHOD OF TESTING A POWER TRANSISTOR

(71) Applicant: SEMICONDUCTOR COMPONENTS INDUSTRIES, LLC, Scottsdale, AZ (US)

(72) Inventors: Wim DOBBELAERE, Ninove (BE); Ronny VANHOOREN, Evergem (BE); Anthony B.G. COYETTE, De Pinte (BE); Sigrid CREMERS, Melle (BE)

(73) Assignee: SEMICONDUCTOR COMPONENTS INDUSTRIES, LLC, Scottsdale, AZ (US)

(21) Appl. No.: 18/647,326

(22) Filed: Apr. 26, 2024

(51) Int. Cl. G01R 31/26; G01R 19/00

(52) U.S. Cl. CPC G01R 31/2608; G01R 19/0038

(57) ABSTRACT

A method can include closing a reset switch electrically coupled to a gate of a transistor such that the gate is at a first voltage, thereby charging the gate, wherein the transistor includes the gate and a source, and the source is electrically coupled to a first voltage supply; placing the gate of the transistor in the high impedance state; opening a reset switch; closing a comparator switch such that the gate is electrically coupled to a first input terminal of a voltage comparator, wherein a second input terminal of the voltage comparator is adapted to receive a detection voltage; and determining whether or not the transistor has a defect is based on an output from the voltage comparator. In an implementation, if too much charge is discharged from the gate during a detection time period after opening the reset switch, a defect is detected.

### FIELD OF THE DISCLOSURE

The present disclosure relates to methods of testing transistors, and more particularly, to testing transistors for defects.

### RELATED ART

A power transistor can be prone to latent defects due to the large size of the transistor. Hard defects, such as particles, can be detected and addressed. However, a latent defect can be difficult to see without destructive testing or examination, and the characteristics of the power transistor with a latent defect can be very close to a known good device. One of the indications of a latent defect is an increased leakage current between the gate and the drain, the gate and the source, or the gate and the channel of the power transistor. The leakage current may be 1 nA or lower and can be difficult to detect accurately. The leakage current can be an indication of a damaged gate, but such a small leakage current can be difficult to measure due to various sources of noise and parasitic leakage currents towards the substrate. A more accurate and quicker test for detecting a damaged gate is desired.

### BRIEF DESCRIPTION OF THE DRAWINGS

Implementations are illustrated by way of example and are not limited in the accompanying figures.

FIG. 1 includes a circuit diagram of a circuit that includes a p-channel power transistor and electronic components for operating and testing the power transistor for defects in accordance with an implementation.

FIG. 2 includes a circuit diagram of a circuit that includes an n-channel power transistor and electronic components for operating and testing the power transistor for defects in accordance with another implementation.

FIG. 3 includes the circuit diagram of FIG. 1 where the p-channel power transistor and defects are represented by electrical circuit elements.

FIG. 4 includes the circuit diagram of FIG. 2 where the n-channel power transistor and defects are represented by electrical circuit elements.

FIG. 5 includes an illustration of a top view of a portion of the power transistor of FIG. 1 or 2 and associated defects.

FIGS. 6 and 7 include a process flow diagram for a method of testing and operating the circuit of FIG. 1.

FIG. 8 includes plots of gate voltage for a p-channel power transistor as a function of time for a reset voltage and a particular detection voltage, wherein different resistances that represent different levels of defects and an output of a comparator as a function of time.

FIG. 9 includes some of the plots of FIG. 8 for the reset voltage and a different detection voltage.

FIG. 10 includes plots of gate voltage for an n-channel power transistor as a function of time for another reset voltage and a particular detection voltage, wherein different resistances that represent different levels of defects and an output of a comparator as a function of time.

FIG. 11 includes some of the plots of FIG. 10 for the other reset voltage and a different detection voltage.

Skilled artisans appreciate that elements in the figures are illustrated for simplicity and clarity and have not necessarily been drawn to scale. For example, the dimensions of some of the elements in the figures may be exaggerated relative to other elements to help improve understanding of implementations of the invention.

### DETAILED DESCRIPTION

The following description in combination with the figures is provided to assist in understanding the teachings disclosed herein. The following discussion will focus on specific implementations of the teachings. This focus is provided to assist in describing the teachings and should not be interpreted as a limitation on the scope or applicability of the teachings. However, other implementations can be used based on the teachings as disclosed in this specification.

The terms “horizontal,” “lateral,” and their variants are in directions along or parallel to a primary surface of a substrate or semiconductor layer, and the terms “vertical” and its variants are in directions perpendicular to a primary surface of the substrate or the semiconductor layer. Two objects that are laterally offset can be at the same or different elevations.

The term “normal operation” and “normal operating conditions” refer to conditions under which an electronic component or device is designed to operate, and not when the electronic component or device is in a test mode. The conditions may be obtained from a data sheet or other information regarding voltages, currents, capacitance, resistance, or other electrical conditions. Thus, normal operation does not include operating an electrical component or device well beyond its design limits.

The term “power transistor” is intended to mean a transistor that is adapted to flow at least 1 A of current when the transistor is in an on-state.

For clarity of the drawings, certain regions of device structures, such as doped regions or dielectric regions, may be illustrated as having generally straight line edges and precise angular corners. However, those skilled in the art understand that, due to the diffusion and activation of dopants or formation of layers, the edges of such regions generally may not be straight lines and that the corners may not be precise angles.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements in between the two elements.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Such differences can be within manufacturing tolerance. Thus, differences of up to ten percent (10%) (and up to twenty percent (20%) for semiconductor doping concentrations) for the value are reasonable differences from the ideal goal of exactly as described.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

A method of testing a transistor can include charging a gate to an initial voltage. After charging is terminated, the gate of the transistor can be electrically coupled to a comparator to determine if the gate voltage increases at least to a detection voltage (for a p-channel transistor) or decreases to or lower than the detection voltage (for an n-channel transistor) within or at the end of a detection time period. The method is more accurate in that, a current is integrated for an amount of time on a capacitor that includes the gate as one of the electrodes. The resulting signal corresponding to the accumulated charge is more stable and easier to measure than the current itself. The test can be performed on the power transistor itself, rather than on a dedicated test structure. The test can be performed quickly and be part of a routine when turning on the power transistor to make sure the power transistor does not have a defect before a load or electrical test equipment receives current or a signal from the power transistor.

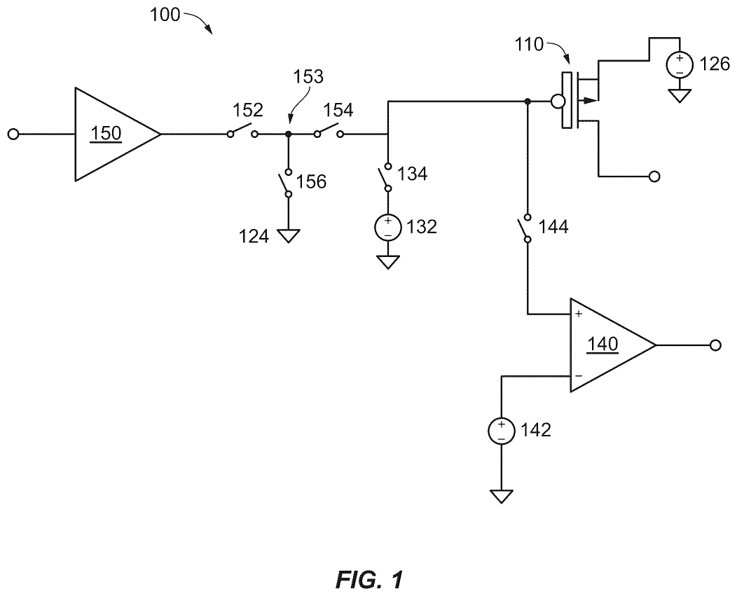

FIG. 1 includes a circuit diagram of a circuit 100 that includes a power transistor 110 and associated electrical circuit elements. The circuit and method described herein can be used with many different transistors and is not limited only to power transistors. Drain current when the transistor is on may be 9 mA or possibly even lower as the transistors are smaller. Still, the circuit and method are well suited for power transistors.

In an implementation, the power transistor 110 is a p-channel insulated gate field-effect transistor (IGFET). The source and body of the power transistor 110 can be electrically coupled to a power supply terminal of the circuit 100 that is electrically coupled to a power supply 126. The drain of the power transistor 110 can be electrically floating during testing. In another implementation, the drain can be electrically connected to the source of the power transistor 110 during testing.

The gate of the power transistor 110 can be electrically coupled to a gate driver 150 that is adapted to provide a potential to the gate of the power transistor 110 to turn on or turn off the power transistor 110. A set of gate switches are configured in a “T-shaped” circuit arrangement that is an exemplary, non-limiting circuit configuration associated with the gate driver 150. Gate switches 152, 154, and 156 are used during normal operation of the power transistor 110. When the circuit 100 is in a normal mode (i.e., not a test mode), the switches 152 and 154 are closed, and the switch 156 is open. In the test mode, the switches 152 and 154 are open, and the switch 156 is closed.

The gate driver switch 152 has a gate driver terminal electrically coupled to the gate driver 150 and a terminal that electrically coupled to a node 153, the gate access switch 154 has a terminal electrically coupled to the node 153 and a gate terminal electrically coupled to the gate of the power transistor 110, and the gate discharge switch 156 has a power supply terminal electrically coupled to the power supply 124 and a switch terminal electrically coupled to the node 153. The gate driver 150 is adapted to provide a potential to the gate of the power transistor 110 such that the gate-to-source voltage (Vas) for the power transistor 110 is at least the threshold voltage (VTH) of the power transistor 110 to turn on the power transistor 110. The power supply 124 is adapted to provide a potential to the gate of the power transistor 110 such Vas for the power transistor 110 is less than VTH of the power transistor 110 to turn off the power transistor 110.

The gate driver 150 can turn the power transistor 110 on and off during normal operation. The gate driver switch 152 and the gate access switch 154 are closed and the gate discharge switch 156 is open. When changing from the normal mode to the test mode, the gate driver switch 152 and the gate access switch 154 are opened, and the gate discharge switch 156 is closed to reduce capacitive coupling between the gate driver 150 and the gate of the power transistor 110. When changing from the test mode to the normal mode, the gate discharge switch 156 is opened, and the gate driver switch 152 and the gate access switch 154 are closed.

The gate of the power transistor 110 can be electrically coupled to a reset switch 134 that is electrically coupled to a reset power supply 132. The reset power supply 132 is adapted to provide a reset voltage (VRESET) and can change a charge of the gate of the power transistor 110 during testing, and thus, change a potential of the gate. The gate access switch 154 is open and the reset switch 134 is closed during a charging portion of a method that tests the power transistor 110.

A comparator 140 can include a positive input terminal and a negative input terminal. The positive input terminal can be electrically coupled to a terminal of comparator switch 144, and another terminal of the comparator switch 144 can be electrically coupled to the gate of the power transistor 110. The negative input terminal of the comparator 140 can be electrically coupled to a detection power supply 142 that is adapted to provide a detection voltage (V_{DETECT}). An output terminal of the comparator 140 can provide an output from the comparator 140. In an implementation, the comparator 140 is adapted to receive analog inputs and output a digital signal. For example, when the potential at the positive terminal of the comparator 140 is less than the potential at the negative terminal, the output terminal of the comparator 140 can be low or have a value of 0, and when the potential at the positive terminal of the comparator 140 is greater than the potential at the negative terminal, the output terminal of the comparator 140 can be high or have a value of 1. The output terminal can be coupled to an electrical circuit element or circuit that can respond appropriately based on the signal from the output terminal.

During normal operation, no defect of the gate is detected, and the power transistor 110 can operate normally. As will be described in more detail later in this specification, a gate defect may be detected. A gate defect associated with the source of the power transistor 110 may be adjacent to the source or the body because the body is electrically connected to the source, and a gate defect associated with the drain of the power transistor 110 may be adjacent to the drain and may include the drain or a drift region (that may be present in the power transistor 110). When a gate defect is present, the potential on the positive terminal of the comparator 140 will increase relatively quickly (as compared to no defect present), and the output of the comparator will change from low to high or from 0 to 1 within the detection time period. The output terminal of the comparator 140 may be coupled to logic that does not allow the gate driver 150 to provide a signal to the gate of the power transistor 110 that would turn on the power transistor 110, logic that provides a signal to an operator that a gate defect has been detected, logic that performs another suitable action in response to the changed output signal from the comparator 140, or a combination thereof.

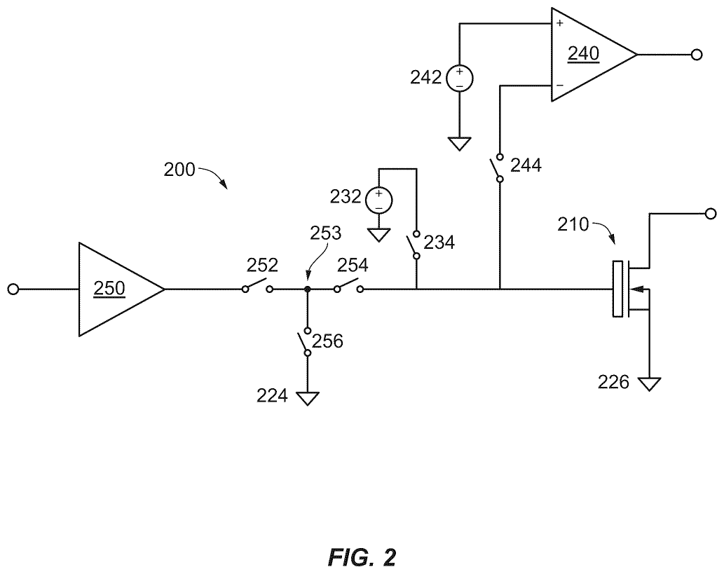

The concepts described above can be modified for use with an n-channel IGFET. FIG. 2 includes a circuit diagram of a circuit 200 that includes a power transistor 210 and associated electrical circuit elements. Similar to circuit 100 in FIG. 1, the circuit and method described herein can be used with many different transistors and is not limited only to power transistors. Drain current when the transistor is on may be 9 mA or possibly even lower. Still, the circuit and method are well suited for power transistors.

In an implementation, the power transistor 210 is an n-channel IGFET. The source and body of the power transistor 210 can be electrically coupled to a power supply terminal of the circuit 200 that is electrically coupled to a power supply 226. In an implementation, the power supply 226 can be ground or provide 0 V to the source of the power transistor 210. The drain of the power transistor 210 can be electrically floating during testing. In another implementation, the drain can be electrically connected to the source of the power transistor 210 during testing.

The gate of the power transistor 210 can be electrically coupled to a gate driver 250 that is adapted to provide a potential to the gate of the power transistor 210 to turn on or turn off the power transistor 210. A set of gate switches are configured in a “T-shaped” circuit arrangement that is an exemplary, non-limiting circuit configuration associated with the gate driver 250. Gate switches 252, 254, and 256 are used during normal operation of the power transistor 210. When the circuit 200 is in a normal mode (i.e., not a test mode), the switches 252 and 254 are closed, and the switch 256 is open. In the test mode, the switches 252 and 254 are open, and the switch 256 is closed.

The gate driver switch 252 has a gate driver terminal electrical coupled to the gate driver 250 and a terminal that is electrically coupled to a node 253, the gate access switch 254 has a terminal electrically coupled to the node 253 and a gate terminal electrically coupled to the gate of the power transistor 210, and the gate discharge switch 256 has a power supply terminal electrically coupled to the power supply 224 and a switch terminal electrically coupled to the node 253. The gate driver 250 is adapted to provide a potential to the gate of the power transistor 210 such that Vos for the power transistor 210 is at least VTH of the power transistor 210 to turn on the power transistor 210. The power supply 224 is adapted to provide a potential to the gate of the power transistor 210 such that Vos for the power transistor 210 is less than VTH of the power transistor 210 to turn off the power transistor 210. In an implementation, the power supply 224 can be ground or provide 0 V.

The gate driver 250 can turn the power transistor 210 on and off during normal operation, the gate driver switch 252 and the gate access switch 254 are closed and the gate discharge switch 256 is open. When changing from the normal mode to the test mode, the gate driver switch 252 and the gate access switch 254 are opened, and the gate discharge switch 256 is closed to reduce capacitive coupling between the gate driver 250 and the gate of the power transistor 210. When changing from the test mode to the normal mode, the gate discharge switch 256 is opened, and the gate driver switch 252 and the gate access switch 254 are closed.

The gate of the power transistor 210 can be electrically coupled to a reset switch 234 that is electrically coupled to a reset power supply 232. The reset power supply 232 is adapted to provide V_{RESET} and can change a charge of the gate of the power transistor 210 during testing, and thus, change a potential of the gate. The gate access switch 254 is open and the reset switch 234 is closed during a charging portion of a method that tests the power transistor 210.

A comparator 240 can include a positive input terminal and a negative input terminal. The positive input terminal of the comparator 240 can be electrically coupled to a detection power supply 242 that is adapted to provide V_{DETECT}. The negative input terminal can be electrically coupled to a terminal of comparator switch 244, and another terminal of the comparator switch 244 can be electrically coupled to the gate of the power transistor 210. An output terminal of the comparator 240 can provide an output from the comparator 240. In an implementation, the comparator 240 is adapted to receive analog inputs and output a digital signal. For example, when the potential at the positive terminal of the comparator 240 is less than the potential at the negative terminal, the output terminal of the comparator 240 can be low or have a value of 0, and when the potential at the positive terminal of the comparator 240 is greater than the potential at the negative terminal, the output terminal of the comparator 240 can be high or have a value of 1. The output terminal can be coupled to an electrical circuit element or circuit that can respond appropriately based on the signal from the output terminal.

During normal operation, no defect of the gate is detected, and the power transistor 210 can operate normally. As will be described in more detail later in this specification, a gate defect may be detected. A gate defect associated with the source of the power transistor 210 may be adjacent to the source or the body because the body is electrically connected to the source, and a gate defect associated with the drain of the power transistor 210 may be adjacent to the drain and may include the drain or a drift region (that may be present in the power transistor 210). When a gate defect is present, the potential on the positive terminal of the comparator 240 will increase relatively quickly (as compared to no defect present), and the output of the comparator will change from low to high or from 0 to 1 within the detection time period. The output terminal of the comparator 240 may be coupled to logic that does not allow the gate driver 250 to provide a signal to the gate of the power transistor 210 that would turn on the power transistor 210, logic that provides a signal to an operator that a gate defect has been detected, logic that performs another suitable action in response to the changed output signal from the comparator 240, or a combination thereof.

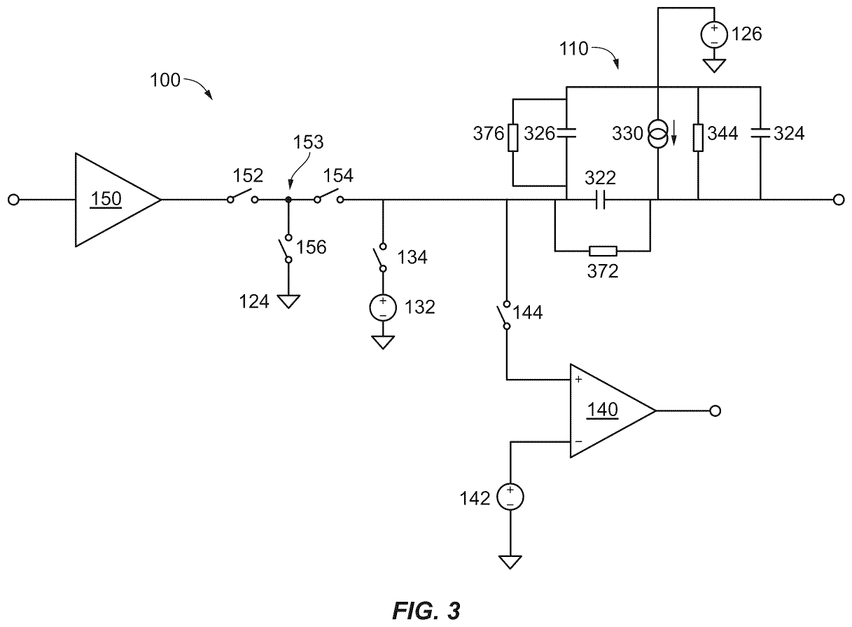

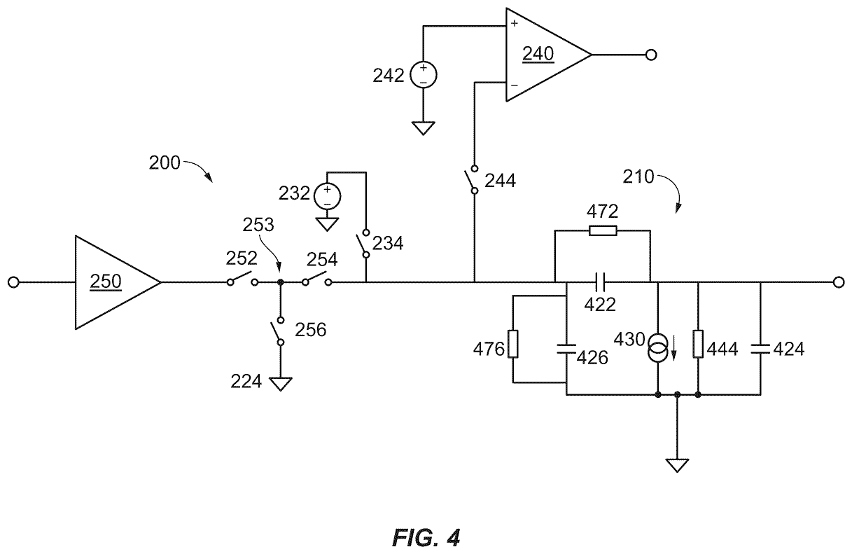

FIGS. 3 and 4 include the circuit 100 and 200 where the power transistors are represented by electrical components used to model the behavior of the power transistors and the defects are represented by resistors. In FIG. 3, the power transistor 110 is represented by capacitors 322, 324, and 326, a current source 330, and a resistor 344, where the capacitor 322 corresponds to the gate-to-drain capacitance (C_{GD}), the capacitor 324 corresponds to the drain-to-source capacitance (C_{DS}), the capacitor 326 corresponds to the gate-to-source capacitance (C_{GS}), and the resistor 344 represents RDSON, which is the on-state resistance for the power transistor 110.

In FIG. 4, the power transistor 210 is represented by capacitors 422, 424, and 426, a current source 430, and a resistor 444, where the capacitor 422 correspond to C_{GD}, the capacitor 424 correspond to C_{DS}, the capacitor 426 correspond to Cos, and the resistor 444 represents R_{DSON}, which is the on-state resistance for the power transistor 210.

A more defective gate correlates to more current flowing between the gate and the source, body, or both or between the gate and the drain. After charging the gate of the power transistor being tested, the current due to the defect reduces the potential across the electrodes for the capacitor 322 or 326 or both capacitors for the power transistor 110 or for the capacitor 422 or 426 or both capacitors for the power transistor 210. Thus, as the drain-side gate defect becomes worse, current flow increases and can be modelled by a smaller resistance value for the resistor 372, and as the source-side gate defect becomes worse, current flow increases and can be modelled by a smaller resistance value for the resistor 376. Similarly, as the drain-side gate defect becomes worse, current flow increases and can be modelled by a smaller resistance value for the resistor 472, and as the source-side gate defect becomes worse, current flow increases and can be modelled by a smaller resistance value for the resistor 476.

In another implementation, the connections of the detection power supply and the comparator switch to the comparator can be switched. Regarding FIG. 1, the detection power supply 142 can be electrically coupled to the positive terminal of the comparator 140, and the comparator switch 144 can be electrically coupled to the negative terminal of the comparator 140. For this implementation, the output of the comparator 140 will be high or 1 when Va is less than V_{DETECT} and will be low or 0 when VG is greater than V_{DETECT}. Regarding FIG. 2, the detection power supply 242 can be electrically coupled to the negative terminal of the comparator 240, and the comparator switch 244 can be electrically coupled to the positive terminal of the comparator 240. For this implementation, the output of the comparator 240 will be high or 1 when Va is greater than V_{DETECT} and will be low or 0 when Va is less than V_{DETECT}.

Before addressing a method of testing the power transistor for a gate defect, potentials for power supplies are addressed. The power supply 126 can provide a potential to the power transistor 110. The potential can correspond to the voltage rating for the power transistor 110, wherein the voltage rating can be obtained from a data sheet for the power transistor 110. If a power transistor 110 does not have a corresponding data sheet, the designed input potential can be used. In the same or different implementation, the input potential can be in a range of 80% (0.8 times) to 100% (1.0 times) the voltage rating or designed input potential. In a non-limiting example, the power transistor 110 can have a voltage rating of 45.0 V, and, in the test mode, the potential received by the source of the power transistor 110 can be 41.0 V. For the power transistor 210, the power supply 226 can be at a relatively low potential. The power supply 226 can be at ground or may provide 0.0 V. In another implementation, the power supply 226 may supply a voltage in a range of-5.0 V to 5.0 V.

The reset power supplies 132 and 232 can provide potentials that have relationship to potentials provided by their corresponding power supplies 126 and 226, respectively. The power supplies 126 and 226 provide a potential to the sources of the power transistors 110 and 210, respectively. In a test mode implementation, the relationship between the potential on the source of the power transistor and the potential provided by its corresponding reset power supply is: 0.1 V≤|(V_{S}−V_{RESET})|≤9.0 V, Equation 1, where: V_{S} is the voltage of the source of the power transistor, and V_{RESET} is the voltage provided by the reset power supply corresponding to the power transistor. Equation 1 includes an absolute value for the difference, so that Equation 1 can be used for p-channel and n-channel power transistors. If needed or desired, a voltage difference outside the range may be used.

When the power transistor 110 is a p-channel IGFET, the reset power supply 132 will provide a lower potential as compared to the power supply 126. In a non-limiting implementation, the V_{S} can be 41.0 V and the reset power supply 132 can provide V_{RESET} of 38.5 V. When the power transistor 210 is an n-channel IGFET, the reset power supply 232 will provide a higher potential as compared to the power supply 226. In a non-limiting implementation, the V_{S} can be 0.0 V and the reset power supply 232 can be a V_{DD} power supply provide V_{RESET} of 2.5 V.

For a power transistor, the detection power supply can provide a potential at a voltage that is between V_{S} and V_{RESET}. The detection power supplies 142 and 242 can provide potentials that have relationship to potentials provided by their corresponding reset supplies 132 and 232, respectively. The detection power supplies 142 and 242 provide a potential to terminals of the comparators 140 and 240, respectively. In an implementation, the relationship between the potential provided by a detection power supply and the potential provided by its corresponding reset power supply is: 0.05 V≤|(V_{DETECT}−V_{RESET})|≤0.9 V, Equation 2, where V_{DETECT} is the voltage provided by the detection power supply corresponding to the power transistor. Equation 2 includes an absolute value for the difference, so that Equation 2 can be used for p-channel and n-channel power transistors. Regarding the lower value, 0.05 V represents a voltage that is sufficient to distinguish the voltage difference from voltage fluctuations associated with parasitic characteristics of the power transistor, noise within the electronic device during testing, or both parasitic characteristics and noise. The upper value for the difference in Equation 2 is less than the difference involving V_{S} for the power transistor in Equation 1. As the V_{DETECT} gets closer to V_{S}, a detection time period may be long and increase the time used to perform the test. The upper value should at least be sufficient to provide sufficiently high confidence that a gate defect is actually detected (i.e., not a false positive or false negative with respect to detection). The upper value of 0.9 V allows high confidence with respect to detection while testing takes acceptably short time. If needed or desired, a voltage difference outside the range may be used.

For the p-channel power transistor 110, the reset power supply 132 can provide a lower potential as compared to the power supply 126. In a non-limiting implementation, the detection power supply 142 can provide V_{DETECT} of 38.7 V, and the reset power supply 132 can provide V_{RESET} of 38.5 V, which is a 0.2 V difference. For the n-channel power transistor 210, the reset power supply 232 can provide a higher potential as compared to the power supply 226. In a non-limiting implementation, the V_{DETECT} can be 2.3 V, and the reset power supply 232 can be a V_{DD} power supply and provide V_{RESET} of 2.5 V, where the absolute value of the difference is 0.2 V.

Many power supplies are addressed above. Each power supply may be an independent power supply or may be an output from a voltage divider of another power supply. For example, the voltage supply 126 and 226 can be stepped down voltage from another power supply, and V_{RESET}, V_{DETECT}, or both can be stepped down from another power supply.

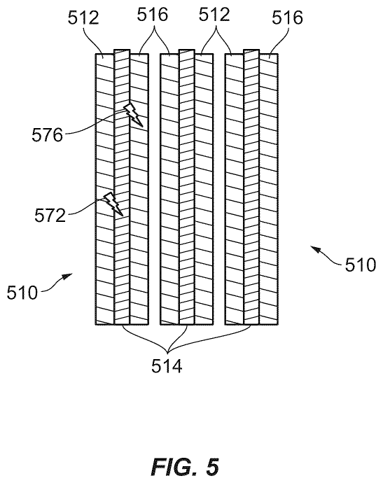

FIG. 5 includes a top view of a portion the power transistor 110 (FIG. 1). The description of the power transistor 110 may also be implemented for the power transistor 210 (FIG. 2). The power transistor 110 includes a plurality of transistor structures 510, three of which are illustrated in FIG. 5. Each transistor structure 510 can include a drain region 512, a gate electrode 514, and a source region 516. In FIG. 5, drift regions can be part of the drain regions 512. As illustrated, the transistor structures 510 are oriented, such that when in an on-state, current flows laterally (flows from the source regions 516, through channel regions under the gate electrode 514 and into the drain regions 512) within the transistor structures 510.

FIG. 5 illustrates gate defects 572 and 576 as lightning bolts. The gate defect 572 is associated with a drain region 512 or a drift region, and the gate defect 576 is associated with a source regions 516, a body region (under a corresponding gate electrode 514) or associated a combination of at least one source region 516 and at least one body region of the transistor structures 510. FIG. 5 illustrates the gate defects 572 and 576 in the transistor structure closest to the left-hand side of FIG. 5. Any one or more other transistor structures may include a gate defect 572 or 576 or both gate defects 572 and 576. In the same or another implementation, the transistor structures 510 for the power transistor 110 may not have any detectable gate defects, the left-hand side transistor structure 510 may have none or one of the gate defects 572 and 576, or one or more other transistor structures 510, including the transistor structures 510 in the center or right-hand side transistor structure 510 in FIG. 5, may have none, one, or both gate defects 572 and 576.

In another implementation for another physical design, the drain may be made with backside metal. The drain regions 512 in FIG. 5 can be replaced by other source regions 516. The gate electrodes 514 overlie a major surface of a substrate in which active regions of the transistor structures are located. When in an on state, initially, current flows laterally from the source regions 516 into the channel regions and then flows vertically (into the drawing sheet for FIG. 5) through most of drift regions of the power transistor 110.

In a further implementation for another physical design, the gate electrodes 514 may be within gate trenches and the drain may be made with backside metal. The drain regions 512 in FIG. 5 can be replaced by other source regions 516. When in an on state, current flows vertically (into the drawing sheet for FIG. 5) from the source regions 516, through channel regions adjacent to the gate trenches the gate electrode 514) and drift regions of the power transistor 110 before reaching the backside metal.

For the power transistor 210, the physical designs can be the same as the power transistor. When in the on-state, current flows from the drain to the source, rather than from the source to the drain as described with respect to the power transistor 110.

Another physical design for the power transistor 110 or 120 can be used. Thus, the physical designs are exemplary and do not limit the concepts described herein. Any of the physical designs can have gate defects as previously described with respect to FIG. 5.

Many of the components have been described with respect to electrical couplings. In an alternative implementation, any or all of the electrical couplings can be electrical connections. For example, any one or a plurality of the switches can be electrically connected to the gate of the power transistor 110 or 120. A resistor (not illustrated) may be along any one or more of the conduction paths that are between power sources and the power transistor 110 or 210, the comparator 140 or 240, or both the power transistor 110 or 210 and its corresponding comparator.

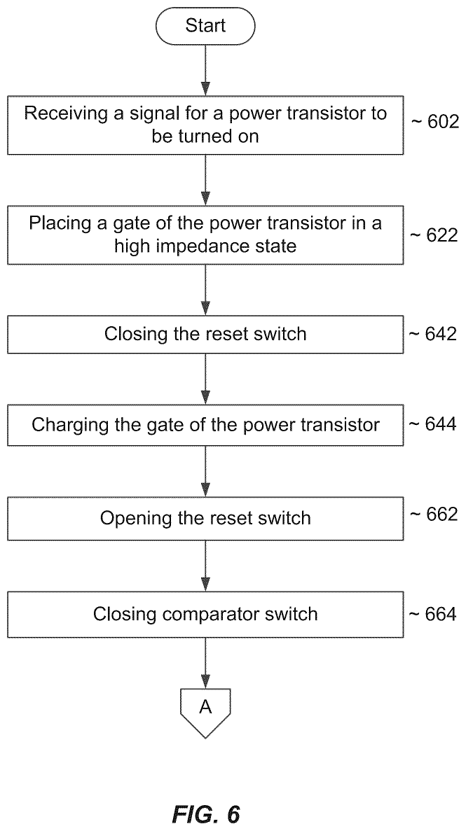

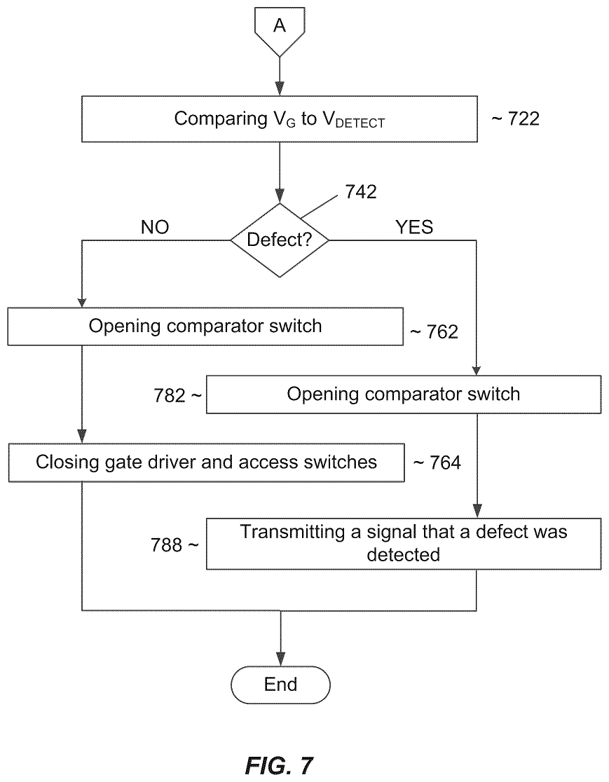

FIGS. 6 and 7 include a flow diagram for a method of using a power transistor. The power transistor may be electrically coupled to a load, where the power transistor provides current to the load, or to electrical testing equipment. If the power transistor has a gate defect, the load or electrical testing equipment may be damaged or operate improperly. The method can be used to assure functional safety of the power transistor before the power transistor is turned on. The method is exemplary, not all actions are required, or further actions may be part of the method. The method is described with respect to the power transistor 110 and can be modified for the power transistor 210.

The method can include receiving a signal for a power transistor to be turned on at block 602 in FIG. 6. In an implementation, the method may be used to perform a safety test before the power transistor is turned on. Such an implementation can substantially reduce the likelihood of damaging or adversely affecting a load or electrical testing equipment coupled to the drain of the power transistor. The test may be performed separately from turning on the power transistor, and thus, the action associated with block 602 is not required for all implementations.

The method can include placing a gate of the power transistor in a high impedance state at block 622 in FIG. 6. The gate of the power transistor 110 can be put into a high impedance state by opening the gate access switch 154. The gate driver switch 152 can be opened, and the gate discharge switch 156 can be closed to reduce capacitive coupling between the gate driver 150 and the gate of the power transistor 110. The reset switch 134 and the comparator switch 144 can be open. If the switches are in the correct positions (opened or closed), no further action is required, and thus, the action in block 622 does not need to be performed for all implementations.

During testing, no or little current (less than 1 nA) may flow between the source and drain of the power transistor 110. The drain of the power transistor 110 can be electrically floating or can be at substantially the same potential as the source of the power transistor (for example, |(V_{S}−V_{D})|<0.05V).

The method can include closing the reset switch and charging the gate of the power transistor at blocks 642 and 644 in FIG. 6. The reset switch 134 is closed and allows the reset power supply 132 to charge the gate of the power transistor 110 to substantially the potential of the reset power supply 132. The potential of the reset power supply 132 can be 0.1 V to 9.0 V lower than V_{S} of the power transistor 110. In an implementation, the reset power supply 132 may provide a potential that is 1.5 V to 4.0 V less than V_{S} of the power transistor 110. The potential of the gate of the power transistor 110 is charged such that the potential of the gate of the power transistor 110 is substantially the same as the reset power supply 132. The charging can be performed for a charging time period in a range of 1 us to 1 ms.

The method can include opening the reset switch and closing the comparator switch at blocks 662 and 664 in FIG. 6 and comparing V_{G} to V_{DETECT} at block 722 in FIG. 7. The method can transition from charging the gate of the power transistor 110 to comparing the potential on the gate of the power transistor 110, V_{G}, to V_{DETECT}. The reset switch 134 can be opened before the comparator switch 144 is closed. During the detection period, current can flow through one of the defect resistors 372 or 376 and change the potential across the respective capacitors 324 and 326. Thus, the capacitors 324 and 326 that were charged when the reset switch 134 was closed can begin to discharge after the reset switch 134 is opened. When and after the comparator switch 144 is closed, the potential of the gate of the power transistor 110 can be transmitted to and received by the comparator 140. The detection power supply 142 can provide a potential that is in a range of 0.05 V to 0.9 V higher than the potential of the reset power supply 132. In a particular implementation, the V_{DETECT} can be 0.1 V to 0.5 V greater than V_{RESET}.

The method can further include determining whether or not the power transistor has a defect at decision diamond 742 in FIG. 7. Different techniques can be used for determining whether or not a defect is detected. When V_{G} is at least V_{DETECT}, the output from the comparator 140 goes from low or 0 to high or 1 and is referred to herein as a change in state of the output.

A detection time period may be used for the determination. The detection time period can have a duration that is sufficient to ensure that a parasitic characteristic or noise does not cause a false negative (actual defect present but not detected) or a false positive (defect detected when no actual defect is present) to occur. A false negative may be more likely to occur if the detection time period is too short, and a false positive may be more likely to occur if the detection time period is too long. In an implementation, the detection time period can be at least 1 ms. As the detection time period increases, the method can take longer to perform. In the same or different implementation, the detection time period may be at most 900 ms. In a particular implementation, the detection time period can be in a range from 1.1 ms to 99 ms.

One of the techniques can include accessing the signal from the comparator 140 immediately or a few ms (for example, up to 5 ms) after the detection time period ends. At the end of the detection time period, if the output of the comparator 140 did not change state, no defect is detected, and if the output of the comparator 140 changed state, a defect is detected. Another technique can be to detect a change in state of the output of the comparator 140 and determine if the change in state occurred before the end of the detection time period. If the change in state occurs before the end of the detection time period, a defect is detected, and no further comparison is required. If the detection time period ends and no change in state of the output is detected, no defect is detected. This technique is faster than the prior technique because the method can be terminated sooner when a defect is detected; however, its implementation may be more complicated or take more processing resources because both accessing the signal at the output and monitoring the detection time period (how much time has elapsed) may use more processing resources. Other techniques for monitoring V_{G} that can be used in detecting whether or not a defect is present may be used without departing from the concepts as described herein.

The method can proceed after the determination in decision diamond 742 is completed. When no defect is detected (NO branch from decision diamond 742), the method can include opening the comparator switch and closing the gate driver and access switches at blocks 762 and 764 in FIG. 7. The comparator switch 144 can be opened after the detection time period ends and may or may not be opened after the detection action in decision diamond 742 is completed. When no defect is detected, the power transistor 110 can be turned on and may provide current to a load coupled to the drain of the power transistor or a signal to electrical testing equipment. The power transistor 110 can be turned on when or after closing the gate driver switch 152 and the gate access switch 154 and opening the gate discharge switch 156. The method may or may not be repeated before the power transistor 110 is to be turned on. The method may be performed each time the power transistor 110 is turned on, using a frequency-of-use basis (e.g., once every 100, 1000, or 1 million times the power transistor is turned on) or using a time period basis (e.g., once daily, weekly, or monthly).

When a defect is detected (YES branch from decision diamond 742), the method can include opening the comparator switch and transmitting a signal that a defect was detected at blocks 782 and 788 in FIG. 7. The comparator switch 144 can be opened after the detection time period ends and may or may not be after the detection action in decision diamond 742 is completed. When a defect is detected, the power transistor 110 should not be turned on. A signal can be transmitted so that a system or an operator is aware that the power transistor 110 has a defect. The system can repeat the method to confirm the defect is present. The system may or may not turn off or complete pending tasks (e.g., stop an instruction queue from sending further instructions to a processor, complete pending data write commands for writing data to a memory, or the like) to reduce the amount of noise when the method is repeated. In another implementation, the system or the operator may transmit a message to a technician to check or replace the power transistor 110. Other actions may be performed regarding the system, such as checking the voltages of the power sources electrically coupled to the power transistor 110 or the comparator 140. A user of the method can determine one or more actions to be taken when a defect is detected where such action(s) are tailored for a particular application. Thus, transmitting the signal in block 788 is not required in all implementations.

The method described above for the p-channel power transistor 110 can be used for the n-channel power transistor 210. Other than the potentials of the power sources and polarity of differences in potentials, the method and operation for the n-channel transistor 210 can be substantially the same as for the p-channel power transistor 110. For the circuit 200 in FIG. 2, the potentials of the power sources can be different and polarity of differences in potentials can be opposite as compared to the circuit 100. For example, the potential of the reset power supply 232 can be 0.1 V to 9.0 V higher than V_{S} of the power transistor 110. In an implementation, the reset power supply 232 may provide a potential that is 1.5 V to 4.0 V higher than V_{S} of the power transistor 210. The detection power supply 242 can provide a potential that is in a range of 0.05 V to 0.9 V lower than V_{RESET}. In a particular implementation, the V_{DETECT} can be 0.1 V to 0.5 V less than V_{RESET}. When V_{G} is reduced to V_{DETECT} or lower, the output from the comparator 240 goes from low or 0 to high or 1.

Many different aspects and implementations are possible. Some of those aspects and implementations are described below. After reading this specification, skilled artisans will appreciate that those aspects and implementations are only illustrative and do not limit the scope of the inventive concepts. Implementations may be in accordance with any one or more of the implementations as listed below.
Implementation 1. A method can include closing a reset switch electrically coupled to a gate of a transistor such that the gate is at a first voltage, wherein the transistor includes a drain, the gate, and a source, and the source is electrically coupled to a first voltage supply; opening the reset switch; closing a comparator switch such that the gate is electrically coupled to a first input terminal of a voltage comparator, wherein a second input terminal of the voltage comparator is adapted to receive a detection voltage; and determining whether or not the transistor has a defect based at least in part on an output from the voltage comparator.
Implementation 2. The method of Implementation 1 further includes placing the gate of the transistor in a high impedance state before closing the reset switch.
Implementation 3. The method of Implementation 2, wherein placing the gate of the transistor in the high impedance state includes opening a gate access switch between a gate driver and the gate of the transistor.
Implementation 4. The method of Implementation 1 further includes:
closing a gate access switch such that a signal from a gate driver is received by the gate of the transistor to turn on the transistor.
Implementation 5. The method of Implementation 4, wherein after closing the gate access switch, a voltage of the drain of the transistor is substantially the same as a voltage of the source of the transistor.
Implementation 6. The method of Implementation 4, wherein determining whether or not the transistor has a defect results in no defect detected, and closing the gate access switch is performed in response to no defect being detected.
Implementation 7. The method of Implementation 6, wherein a load or test equipment is electrically coupled to the transistor.
Implementation 8. The method of Implementation 6, wherein determining whether or not the transistor has the defect includes determining whether a gate voltage on the gate of the transistor reaches at least the detection voltage at or within a detection time period.
Implementation 9. The method of Implementation 8, wherein determining whether or not the transistor has the defect is performed such that the detection time period is at most 0.9 s.
Implementation 10. The method of Implementation 1, wherein determining whether or not the transistor has a defect results in the defect being detected, and keeping a gate access switch open in response to the defect being detected.
Implementation 11. A method can include charging a gate of a transistor, wherein the transistor includes the gate and a source and a drain; terminating the charging of the gate of the transistor; comparing a gate voltage of the gate to a detection voltage at or after terminating the charging of the gate of the transistor; and determining whether or not the transistor has a defect based at least in part on comparing the gate voltage of the gate to the detection voltage.
Implementation 12. The method of Implementation 11, wherein determining whether or not the transistor has the defect includes determining whether the gate voltage on the gate of the transistor reaches at least the detection voltage at or within a detection time period.
Implementation 13. The method of Implementation 12 further includes placing the source of the transistor at a source voltage, wherein when terminating the charging of the gate of the transistor, the detection voltage is between the source voltage and the gate voltage.
Implementation 14. A method can include closing a reset switch electrically coupled to a gate of a transistor such that the gate is at a first voltage, wherein the transistor includes a drain, the gate, and a source, and the source is electrically coupled to a first voltage supply; opening the reset switch; closing a comparator switch such that the gate is electrically coupled to a first input terminal of a voltage comparator, wherein a second input terminal of the voltage comparator is adapted to receive a detection voltage; and determining whether or not a gate voltage on the gate of the transistor reaches at least the detection voltage at or within a detection time period that is at most 0.9 s. When the transistor is a p-channel transistor, a defect is detected when the gate voltage is at least the detection voltage at an end of or within the detection time period, and no defect is detected when the gate voltage is less than the detection voltage at or after the end of the detection time period. When the transistor is an n-channel transistor, a defect is detected when the gate voltage is at most the detection voltage at an end of or within the detection time period, and no defect is detected when the gate voltage is greater than the detection voltage at or after the end of the detection time period.
Implementation 15. The method of Implementation 14, wherein 0.05 V≤|(V_{DETECT}−V_{RESET})|≤0.9 V, where V_{DETECT} is the detection voltage, and V_{RESET} is a reset voltage.
Implementation 16. The method of Implementation 14, wherein the source of the transistor is adapted to receive a source voltage, 0.1 V≤|(V_{S}−V_{RESET})|≤9.0 V, where V_{S} is the source voltage, and V_{RESET} is a reset voltage.
Implementation 17. The method of Implementation 16, wherein the drain of the transistor is adapted to receive the source voltage when closing the comparator switch.
Implementation 18. The method of Implementation 14 further includes completing a current path between the transistor and a load. The gate voltage did not reach the detection voltage at or within the detection time period. Completing the current path is performed after the gate voltage on the gate of the transistor did not reach the detection voltage at or within the detection time period.
Implementation 19. The method of Implementation 14 further includes transmitting a signal to a test equipment. The gate voltage on the gate of the transistor did not reach the detection voltage at or within a detection time period. Sending the signal is performed after the gate voltage on the gate of the transistor did not reach the detection voltage at or within the detection time period.
Implementation 20. The method of Implementation 14 further includes transmitting a signal. The gate voltage on the gate of the transistor reached the detection voltage at or within a detection time period. Transmitting the signal corresponds to the defect being detected and is performed after the gate voltage on the gate of the transistor reached the detection voltage at or within the detection time period.

### EXAMPLES

The examples below demonstrate how different levels of defects can affect how quickly charge on a gate of a power transistor can be changed and, depending on V_{RESET}, V_{DETECT}, and the detection time period, whether a defect is detected.

Example 1 is based on a simulation of a p-channel transistor that uses the circuit 100 for resetting and then charging the gate of the transistor. The transistor is a p-channel laterally diffused metal-oxide-semiconductor (pLDMOS) power transistor having an input voltage rating of 45 V. C_{GD} for the transistor is approximately 41 pF, and Cas for the transistor is approximately 67 pF. V_{S} is 41.0 V, V_{DETECT} is 38.7 V and V_{RESET} is 38.5 V.

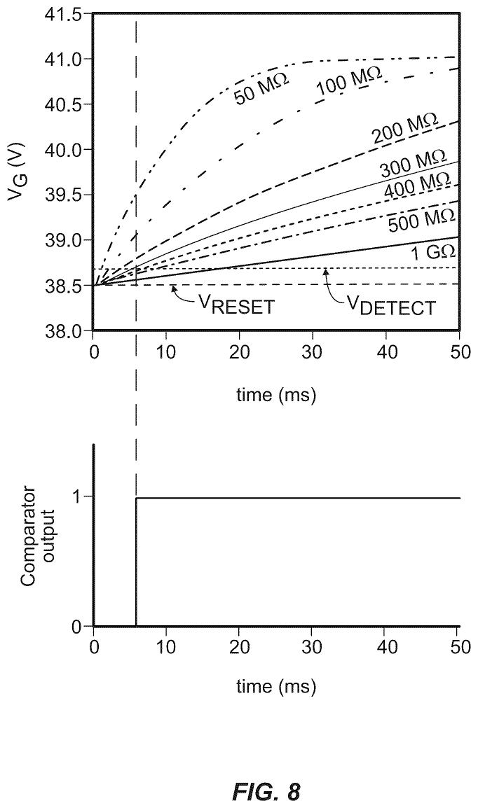

FIG. 8 includes plots of V_{G} for the power transistor 110 as a function of time for resistances of 50 MΩ, 100 MΩ, 200 MΩ, 300 MΩ, 400 MΩ, 500 MΩ, and 1 GΩ. FIG. 8 further includes the output from the comparator 140 as a function of time for the 300 MΩ plot to illustrate when the output from the comparator 140 changes state. Other plots for the comparator 140 can be illustrated in the comparator output signal response but are not illustrated to simplify understanding of how the output of the comparator 140 changes state when V_{G} crosses V_{DETECT}.

The lower resistances correspond to a more defective gate, and the higher resistances correspond to a less defective gate. For a detection time period of 6 ms, a gate defect that corresponds to 300 MΩ and lower resistances will result in a detected defect, and no gate defect or a gate defect corresponding to a resistance higher than 300 MΩ will result in no detected defect.

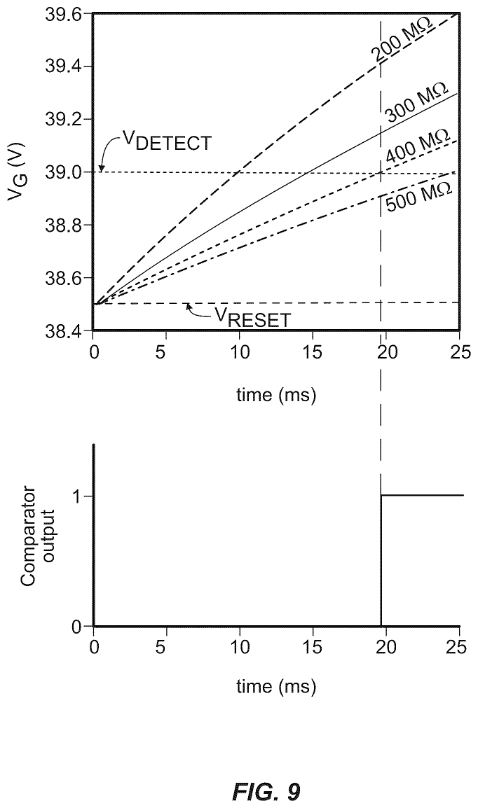

In another implementation, V_{DETECT} can be changed to 39.0 V, so that potentials of the reset power supply 132 and the detection power supply 142 have a 0.5 V difference. The detection time period may be set to 20 ms. FIG. 9 includes plots of V_{G} for the power transistor 110 as a function of time for resistances of 200 MΩ, 300 MΩ, 400 MΩ, and 500 MΩ. FIG. 9 further includes the output from the comparator 140 as a function of time for the 400 MΩ plot to illustrate when the output from the comparator 140 changes state. Other plots for the comparator 140 can be illustrated in the comparator output signal response but are not illustrated to simplify understanding of how the output of the comparator 140 changes state when V_{G} crosses V_{DETECT}.

For this implementation, a gate defect that corresponds to 410 MΩ and lower resistances will result in a detected defect, and no gate defect or a gate defect corresponding to a resistance higher than 410 MΩ will result in no detected defect. The resistance of 400 MΩ is reached in 19 ms, which is less than 20 ms. Thus, the power transistor 110 will be detected as having a gate defect because V_{G} is greater than 39.0 V at 20 ms.

Example 2 is based on a simulation of an n-channel transistor that uses the circuit 200 for charging the gate of the transistor. The transistor is a n-channel laterally diffused metal-oxide-semiconductor (nLDMOS) power transistor having an input voltage rating of 45 V. C_{GD} for the transistor is approximately 47 pF, and Cos for the transistor is approximately 55 pF. V_{S}, is 0.0 V, V_{DETECT} is 2.3 V and V_{RESET} is 2.5 V.

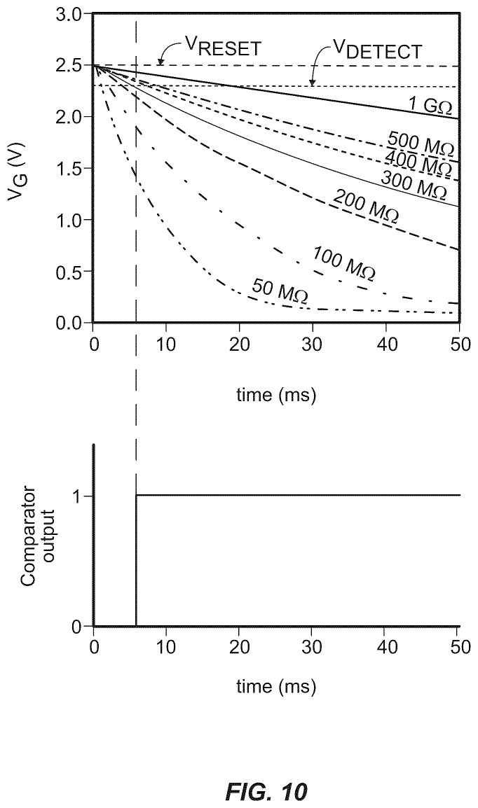

FIG. 10 includes plots of V_{G} of the power transistor 210 as a function of time for resistances of 50 MΩ, 100 MΩ, 200 MΩ, 300 MΩ, 400 MΩ, 500 MΩ, and 1 GΩ. FIG. 9 further includes the output from the comparator 240 as a function of time for the 300 MΩ plot to illustrate when the output from the comparator 240 changes state.

The lower resistances correspond to a more defective gate, and the higher resistances correspond to a less defective gate. For a detection time period of 6 ms, a gate defect that corresponds to 320 MΩ and lower resistances will result in a detected defect, and no gate defect or a gate defect corresponding to a resistance higher than 320 MΩ will result in no detected defect.

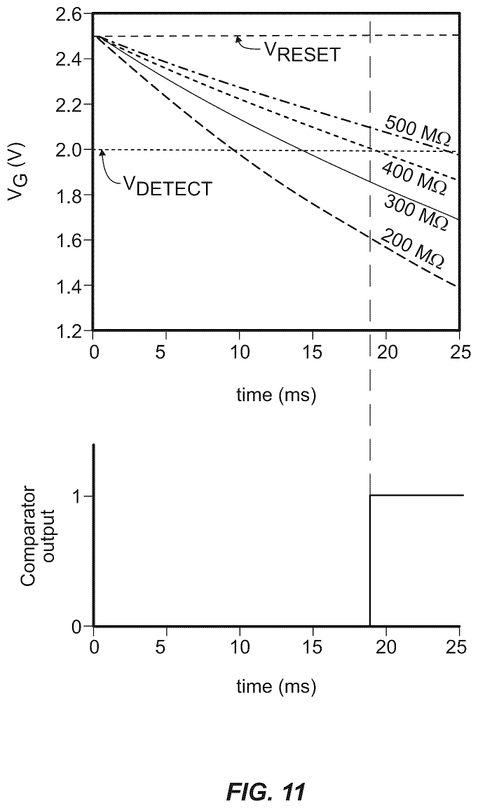

In another implementation, V_{DETECT} can be changed to 2.0 V, so that potentials of the reset power supply 232 and the detection power supply 242 have a difference of 0.5 V. The detection time period may be set to 20 ms. FIG. 11 includes plots of V_{G} for the power transistor 210 as a function of time for resistances of 200 MΩ, 300 MΩ, 400 MΩ, and 500 MΩ. FIG. 11 further includes the output from the comparator 240 as a function of time for the 400 MΩ plot to illustrate then the output from the comparator 240 changes state. Other plots for the comparator 240 can be illustrated in the comparator output signal response but are not illustrated to simplify understanding of how the output of the comparator 240 changes state when V_{G} crosses V_{DETECT}.

For this implementation, a gate defect that corresponds to 410 MΩ and lower resistances will result in a detected defect, and no gate defect or a gate defect corresponding to a resistance higher than 410 MΩ will result in no detected defect. The resistance of 400 MΩ is reached in 19 ms, which is less than 20 ms. Thus, the power transistor 210 will be detected as having a gate defect because V_{G} is less than 2.0 V at 20 ms.

The examples were based on power transistors that have voltage rating of 45 V. The inventive concepts may be used with circuits that have power transistors that have significantly lower voltage ratings, such as 12 V as used for energy converters in personal computers, laptops, etc. or significantly higher voltage rating, such as at least 100 V or over 1000 V that may be used in electronic vehicles. The voltage ratings are exemplary, and power transistors with other voltage ratings may be used.

Implementations as described herein provide benefits regarding testing of power transistors. A circuit can be used to charge a gate of a power transistor and then using a comparator to determine if the power transistor has a defect. After charging, when a defect is present, the voltage on the gate may become closer to a voltage on a source of the power transistor. For a p-channel power transistor, V_{G} may increase toward V_{DETECT}. If V_{G} is at least V_{DETECT} at or before or at the end of a detection time period, a defect is detected. Otherwise, no defect is detected. For an n-channel power transistor, V_{G} may decrease toward V_{DETECT}. If V_{G} is at or lower than V_{DETECT} at or before or at the end of a detection time period, a defect is detected. Otherwise, no defect is detected. The test can be performed before the power transistor is turned on to ensure the power transistor is operating correctly and does not damage or cause a downstream load or electrical testing equipment to operate improperly.

During a comparison portion of the test, current can flow into or from the gate of the power transistor, and the current can affect the voltage of the gate. Tests that monitor current may not be sensitive enough to detect some defects, and particularly small defects or defects that are in an early stage of development. Unlike such methods, a current is integrated for an amount of time on a capacitor that includes the gate as one of the capacitor electrodes. The resulting signal corresponding to the accumulated charge is more stable and easier to measure than the current itself.

The power transistor, itself, as opposed to a dedicated test structure can be used for the test. Thus, area of a substrate, such as a wafer, is not lost to a dedicated test structure. Furthermore, issues with differences between the power transistor and a dedicated test structure are obviated because a dedicated test structure is not required.

With the possible exception of power supplies, the power transistor and all other electrical circuit elements can be on the same die. Thus, the test circuit can be part of a built-in self test circuit. The test can be performed quickly and take less than one second. If needed or desired, part of the circuit may be outside the die. Such a design may cause the test to take longer to perform. Skilled artisans will be able to determine a design for the test circuit that meets the needs or desires for an application.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations may also be provided in combination in a single implementation, and conversely, various features that are, for brevity, described in the context of a single implementation, may also be provided separately or in any subcombination. Further, reference to values stated in ranges includes each and every value within that range. Many other implementations may be apparent to skilled artisans only after reading this specification. Other implementations may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A method, comprising:
closing a reset switch electrically coupled to a gate of a transistor such that the gate is at a first voltage, wherein the transistor includes a drain, the gate, and a source, and the source is electrically coupled to a first voltage supply;
opening the reset switch;
closing a comparator switch such that the gate is electrically coupled to a first input terminal of a voltage comparator, wherein a second input terminal of the voltage comparator is adapted to receive a detection voltage; and
determining whether or not the transistor has a defect based at least in part on an output from the voltage comparator.

2. The method of claim 1, further comprising:
placing the gate of the transistor in a high impedance state before closing the reset switch.

3. The method of claim 2, wherein placing the gate of the transistor in the high impedance state comprises opening a gate access switch between a gate driver and the gate of the transistor.

4. The method of claim 1, further comprising:
closing a gate access switch such that a signal from a gate driver is received by the gate of the transistor to turn on the transistor.

5. The method of claim 4, wherein after closing the gate access switch, a voltage of the drain of the transistor is substantially the same as a voltage of the source of the transistor.

6. The method of claim 4, wherein:
determining whether or not the transistor has a defect results in no defect detected, and closing the gate access switch is performed in response to no defect being detected.

7. The method of claim 6, wherein a load or test equipment is electrically coupled to the transistor.

8. The method of claim 6, wherein determining whether or not the transistor has the defect comprises:
determining whether a gate voltage on the gate of the transistor reaches at least the detection voltage at or within a detection time period.

9. The method of claim 8, wherein determining whether or not the transistor has the defect is performed such that the detection time period is at most 0.9 s.

10. The method of claim 1, wherein:
determining whether or not the transistor has a defect results in the defect being detected, and
keeping a gate access switch open in response to the defect being detected.

11. A method, comprising:
charging a gate of a transistor, wherein the transistor includes the gate and a source and a drain;
terminating the charging of the gate of the transistor;
comparing a gate voltage of the gate to a detection voltage at or after terminating the charging of the gate of the transistor; and
determining whether or not the transistor has a defect based at least in part on comparing the gate voltage of the gate to the detection voltage.

12. The method of claim 11, wherein determining whether or not the transistor has the defect comprises determining whether the gate voltage on the gate of the transistor reaches at least the detection voltage at or within a detection time period.

13. The method of claim 12, further comprising:
placing the source of the transistor at a source voltage, wherein when terminating the charging of the gate of the transistor, the detection voltage is between the source voltage and the gate voltage.

14. A method, comprising:
closing a reset switch electrically coupled to a gate of a transistor such that the gate is at a first voltage, wherein the transistor includes a drain, the gate, and a source, and the source is electrically coupled to a first voltage supply;
opening the reset switch;
closing a comparator switch such that the gate is electrically coupled to a first input terminal of a voltage comparator, wherein a second input terminal of the voltage comparator is adapted to receive a detection voltage; and
determining whether or not a gate voltage on the gate of the transistor reaches at least the detection voltage at or within a detection time period that is at most 0.9 s, wherein:
when the transistor is a p-channel transistor:
a defect is detected when the gate voltage is at least the detection voltage at an end of or within the detection time period, and
no defect is detected when the gate voltage is less than the detection voltage at or after the end of the detection time period, and
when the transistor is an n-channel transistor:
a defect is detected when the gate voltage is at most the detection voltage at an end of or within the detection time period, and
no defect is detected when the gate voltage is greater than the detection voltage at or after the end of the detection time period.

15. The method of claim 14, wherein:
0.05 V≤|(V_{DETECT}−V_{RESET})|≤0.9 V,
where V_{DETECT} is the detection voltage, and V_{RESET} is a reset voltage.

16. The method of claim 14, wherein:
the source of the transistor is adapted to receive a source voltage,
0.1 V≤|(V_{S}−V_{RESET})|≤9.0 V,
where V_{S} is the source voltage, and V_{RESET} is a reset voltage.

17. The method of claim 16, wherein:
the drain of the transistor is adapted to receive the source voltage when closing the comparator switch.

18. The method of claim 14, further comprising completing a current path between the transistor and a load, wherein:
the gate voltage did not reach the detection voltage at or within the detection time period, and
completing the current path is performed after the gate voltage on the gate of the transistor did not reach the detection voltage at or within the detection time period.

19. The method of claim 14, further comprising transmitting a signal to a test equipment, wherein:
the gate voltage on the gate of the transistor did not reach the detection voltage at or within a detection time period, and
sending the signal is performed after the gate voltage on the gate of the transistor did not reach the detection voltage at or within the detection time period.

20. The method of claim 14, further comprising transmitting a signal, wherein:
the gate voltage on the gate of the transistor reached the detection voltage at or within a detection time period, and
transmitting the signal corresponds to the defect being detected and is performed after the gate voltage on the gate of the transistor reached the detection voltage at or within the detection time period.
